(19) United States
(12) Patent Application Publication
(10) Pub. No.: US 2017/0055344 A1
(43) Pub. Date: Feb. 23, 2017

(54) RADAR SYSTEM FOR REGISTERING THE ENVIRONMENT FOR A MOTOR VEHICLE AND A CIRCUIT BOARD FOR SUCH A RADAR SYSTEM

(71) Applicant: Conti Temic microelectronic GmbH, Nürnberg (DE)

(72) Inventor: Michael Menge, München (DE)

(73) Assignee: Conti Temic microelectronic GmbH, Nürnberg (DE)

(21) Appl. No.: 15/305,471

(22) PCT Filed: Feb. 2, 2015
(86) PCT No.: PCT/DE2015/200246

§ 371 Date: Oct. 20, 2016

(30) Foreign Application Priority Data
Apr. 22, 2014 (DE) 10 2014 207 571.8

(51) Int. Cl. H05K 1/02; G01S 7/03; G01S 13/93; H05K 1/11; H01P 3/08

(52) U.S. Cl. CPC H05K 1/0246; H05K 1/115; H01P 3/08; H05K 1/0298; G01S 13/931; G01S 7/03

(57) ABSTRACT

The disclosure relates to a radar system for registering the environment for a motor vehicle, with a circuit board includes a wave termination with a termination line, a signal line connected to it for the transmission of a high frequency signal, and a first substrate layer which is produced from a material with a first loss factor. The radar system also includes a first tier attached onto the first substrate layer, which includes the signal line, a second substrate layer which is produced from a second material with a second loss factor, which is greater than the first loss factor, and a second tier applied to the second substrate layer, which includes the termination line. Additionally, the disclosure relates to a circuit board for such a radar system.

### TECHNICAL FIELD

The disclosure relates to a radar system for registering the environment of a motor vehicle and a circuit board for such a radar system.

### BACKGROUND

Radar systems are found, for example, in both driven and autonomous motor vehicles, construction machines, or production plants. In particular, in a motor vehicle driven by a driver, radar systems determine values of certain environmental parameters, such as a distance of the motor vehicle to another object, as a result of which for example the decision-making of the driver is supported, or a warning may be issued with regard to safety risks. In particular, radar systems for measuring the distance are being used with increasing frequency, for example as parking aids or collision warning systems in motor vehicles.

Such radar systems are operated in the high frequency range in particular, also known as the HF range. This range includes for example a frequency ranging from 10 GHz to 100 GHz. Further, such radar systems usually include HF electronics with corresponding HF components, for example HF transmitters and receivers and suitable antennae. These are arranged on a circuit board and suitably connected to each other. The circuit board here includes a substrate layer, on which in order to transmit a high frequency signal in particular, a line is attached made of an electrically conducting material. The substrate layer is here typically produced from a dielectric material, which is characterised by the lowest loss factor possible in order to transmit the signal with as little loss as possible. The loss factor is a measure for the relationship between the active resistance and blind resistance of the material, and is frequently given as the so-called loss angle or as a tangent of this loss angle.

Further, typically at least one wave termination (also known as termination resistance or wave sump) is provided, for example for adapting the impedance of a signal connection of the radar system. For this purpose, the wave termination is connected to a line end of a signal line. Here, a requirement of a wave termination is that its level of reflection should be as low as possible, i.e., its level of loss is in particular as low as possible. In other words, a signal entering by means of the signal line is as highly absorbed as possible and in particular is not reflective, or only reflective at a low level.

For this purpose, it is possible for example to arrange on the end of the line a so-called absorber mat, which is produced from a high-loss material. This is adhered for example as an additional layer onto the substrate layer such that the end of the line is framed by the absorber mat. For example, it is known from JPH09139608 that in order to cap the end of a strip-shaped line, the line is framed on the end side with a U-shaped thin-layer resistance. The high-loss material used is typically expensive. Further, the application of the absorber mat is an additional process step in the production of the circuit board. Furthermore, sufficient space is required on the substrate layer to house the absorber mat, as a result of which the circuit board must have a correspondingly large design.

Alternatively, it is possible to solder on a wave termination, for example in the form of an SMD, as a separate component, and to connect it to the end of the line. Such components are however only available for a limited frequency range and in particular for frequencies that are too low for radar systems. Furthermore, such components are typically expensive.

A further alternative is a use of an antenna as a wave termination. The signal entering in such a wave termination is then radiated. With radar systems in particular, however, further antennae are frequently provided the functionality of which is impaired by a wave termination designed as an antenna; particularly since these typically transmit and/or receive signals of the same frequency. A wave termination of this type is therefore unsuitable for radar systems.

### SUMMARY

As such, it is desirable to provide an improved radar system. Here, a circuit board that can be produced in as simple and low-cost manner is provided for the radar system. For this purpose, a wave termination is provided which is suitable for the radar system.

The radar system for registering the environment for a motor vehicle includes a circuit board designed, for example, as a multiple layer circuit board. A multiple layer circuit board is understood in particular as being one in which the circuit board includes several layers produced from an electrically conductive material, such as copper, which by means of a number of substrate layers are connected in a stacking direction to form a stack. In some examples, the substrate layers are respectively produced from a dielectric material. The circuit board includes a signal line for transmitting a high frequency signal. Additionally, the circuit board includes a wave termination with a termination line which is connected to the signal line. In other words, the wave termination concludes the signal line by means of the termination line. Additionally, the circuit board includes a first substrate layer which is produced from a first material with a first loss factor, and a first tier attached to the first substrate layer which includes the signal line. This means that the signal line is arranged in the first tier and on the first substrate layer. Additionally, the circuit board includes a second substrate layer that is produced from a second material with a second loss factor, which is higher than the first loss factor, and a second tier attached to the second substrate layer which includes a termination line. This means that the termination line is arranged in the second tier. The termination line and the signal line are respectively also generally referred to below as “line”.

In some examples, the first tier is not the same as the second tier, i.e., the first and the second tier are not both arranged between the first and the second substrate layer. For example, the first tier is designed as a top tier or external tier, i.e., the first tier is attached on the upper side of the circuit board. This makes it possible to advantageously design the signal line as a micro-stripline, also referred to as a microstrip. Such a signal line may be produced at a low cost and in a simple manner.

A high frequency signal in particular with an electromagnetic field assigned to it is typically not exclusively guided within the respective line, but the field also interacts with the material that surrounds the line. As a result, the substrate layer on which the respective tier is attached, depending on the material from which this substrate layer is produced, has a corresponding influence on the guided signal.

A weakening, damping, or absorption of the signal is in particular achieved in the wave termination by the fact that the latter guides or orients the signal from the comparatively low-loss first tier into the comparatively high-loss second tier. Here, low loss and high loss are understood as meaning that the respective tier is attached on a substrate layer that is produced from a low-loss or high-loss material. The weakening is quantified in particular by the loss factor, which in particular designates the so-called loss angle of the respective material or also the tangent of this loss angle, the so-called loss tangent. The lower the loss factor of the material of a specific substrate layer, the lower the loss level of the guidance of the signal by means of a line attached on this substrate layer. In particular, the loss factor is frequency dependent. Then, low loss and high loss are intended in particular to mean that with a given frequency, the loss factor of the material of the respective substrate layer is lower or higher compared to the loss factor of the material of another substrate layer. According to the disclosure, the wave termination guides a signal guided on a low loss tier into a high loss tier.

A circuit board for a high frequency application, for examples, for a radar system, is frequently designed as a multiple layer board with a low loss substrate layer for a high frequency signal and at least one high loss, yet typically cheaper, substrate layer. In some examples, for the low loss layer, the material available under the brand name RO3003 and for the high loss layer a fibre strengthening epoxy resin is used as is known under the material name FR4. The high loss, cheaper substrate layer usually serves to retain further non-HF electronic components. In some examples, a particularly simple, low-cost wave termination can be realised in particular by means of the fact that no additional components or absorber layers (such as absorber mats) are needed to form the wave termination. The wave termination is advantageously only produced from the substrate layers and tiers that are anyway provided to form the circuit board. Such a wave termination additionally advantageously has a low reflection level, i.e., a largest possible share, in particular more than 90% of the signal entering the wave termination, is absorbed by it.

In some implementations, the termination line and the signal line are connected by means of a hollow line, as a result of which in particular a suitable connection is provided between the two tiers. Since the two tiers may have different loss levels for the high frequency signal in particular, the two tiers are arranged separated from each other by at least one substrate layer and if possible other tiers. By means of the hollow line, it is then in particular possible to guide the signal from the first tier through this substrate layer and possibly further substrate layers and/or tiers and finally into the second tier.

Here the hollow line is designed as a so-called SIW (Substrate Integrated Waveguide). In other words, the hollow line includes a hollow line chamber which lies in one of the substrate layers. In particular, the hollow line chamber is therefore filled with the corresponding material. The hollow line includes a number of vertical and horizontal hollow line walls which limit the hollow line chamber. The horizontal hollow line walls are here designed within one of the tiers respectively; the vertical hollow line walls essentially extend vertically to them, i.e., in particular in the stacking direction. Here, the hollow line walls respectively run at least partially through one or more of the substrate layers. Advantageously, the hollow line walls are produced from a conductive material, in particular from the same material as the tiers.

In order to transmit the signal from the signal line into the hollow line and from the hollow line into the termination line, suitable transition areas are provided. In the case of a signal line designed as a micro-stripline, for example, a line strip (also known as a taper) which continuously broadens is provided in the direction of the hollow line. Alternatively, for example, the signal line itself is designed as a hollow line and is directly connected to the hollow line of the wave termination.

Advantageously, the hollow line includes a first section which is arranged in the first substrate layer and a second section which is arranged in the second substrate layer. As a result it is possible to guide the signal from the low loss first substrate layer into the high loss second substrate layer.

In some implementations, a first mass tier is arranged between the first and the second substrate layer. In some examples, this is then also arranged between the first and the second layer. In other words, the mass tier is framed by two substrate layers, which in turn are framed by the two tiers. In this manner, a three-tier structure is realised. The first mass tier may serve as a mass tier in the case of a signal line designed as a micro-stripline. In this case, the signal line is a strip attached on the first substrate layer as a part of the first tier and the mass layer is arranged on the side of the first substrate layer opposite this strip.

In some examples, the mass tier serves as a horizontal hollow line wall, i.e., one which extends vertically to the stacking direction. The first section of the hollow line is then limited by a part of the first mass tier and a part of the first tier; the second section is limited by a further part of the first mass tier and a part of the second tier. In some examples, the same part of the first mass tier serves as a horizontal hollow line wall of both sections.

In particular, in a preferred further development, an opening is inserted into the first mass tier, i.e., the mass tier is not designed to be continuous, but instead includes an area that has been removed. The opening is advantageously implemented in the part of the first mass tier which is a horizontal wall of the hollow line. This enables a particularly low reflective or even reflection-free further guidance of the signal from the first section of the hollow line into its second section. The signal line and the termination line are then in particular connected in such a manner that the signal can be guided from the first tier through the first substrate layer, through the opening, through the second substrate layer, and finally into the second tier.

In some implementations, the opening is designed as a coupling slit. Here, a coupling slit is understood as being an opening which extends over a certain slit width between two opposite vertical walls and vertical to them and includes a certain slit length on the plane of the first mass tier. For example, the slit width and/or the slit length are selected depending on the frequency of the signal. The slit width may essentially correspond to a distance between two opposite vertical hollow line walls. For example, the slit width totals approximately 1.4 mm. In some examples, the slit length totals one tenth to one twentieth of the slit width, e.g., 0.1 mm. In particular, through a suitable selection of the slit length, an advantageous filter effect may be obtained for the signal transmitted through the coupling slit. In some examples a larger slit length enables a transmission of a greater frequency range, i.e., the filter effect is reduced. In some implementations, the opening is designed as a through contact, for example as a so-called Via. This here extends in particular at least over those substrate layers in which the hollow line is arranged.

In some implementations, the first tier, the first mass tier, and the second tier are connected by means of a number of through contacts. These are designed for example as Vias, i.e., in particular as bore holes with metallised inner walls. Alternatively, the through contacts are designed as metallised grooves. In this manner, several tiers can be connected to each other in an electrically conducting manner and accordingly include a shared electrical potential. As a result, it is possible to bring the horizontal hollow line walls to a shared electrical potential, in particular a mass potential.

Advantageously, the through contacts form a hollow line wall, for example, all vertical hollow line walls of the hollow line. As a result, a suitable hollow line is created the walls of which are advantageously connected to each other in an electrically conducting manner. In the case of through contacts connected with the first mass area, the first section is further advantageously short circuited, which results in an improved reflection behaviour in the sense of reduced reflection.

In some implementations, the through contacts are arranged in a U shape with two side arms and a middle arm which connects these. These arms in particular form the vertical walls of the hollow line. Each of the two sections then includes an open end on which accordingly the signal line or the termination line can be connected. Furthermore, each of the sections includes a closed end, which is in particular formed by the middle arm. In some examples, the opening is arranged at a suitable distance from the middle arm, and in particular one which is selected depending on the frequency of the signal. The signal may lie in the hollow line as a standing wave with a wavelength that depends on the frequency. Therefore, the coupling slit is advantageously arranged at a maximum of the standing wave. Advantageously, the distance thus totals around half of the wavelength or in addition to it a whole-figure multiple of half the wavelength. As a result, the signal may be transmitted from the first into the second section with a particularly low reflection level.

In particular, the first and the second section of the hollow line are arranged one on top of the other, i.e., the areas of the two substrate layers which are respectively framed by the sections lie on top of each other in the multiple layer structure of the hollow line. In particular, a part of the first mass tier between the two areas forms both a horizontal hollow line wall of the first section as well as of the second section. In this part of the mass tier, the opening for transmitting the signal may be inserted from the first to the second section.

Each of the through contacts may include an upper part, i.e., one that is arranged in the first substrate layer, and a lower part arranged in the second substrate layer. In some examples, the upper parts then form the vertical hollow line walls of the first section; the lower parts form the vertical hollow line walls of the second section. The hollow line may then pursue a U-shaped progression, which however is not the same as the U-shaped progression of the through contacts.

In some implementations, the termination line is designed in a meandering form or as a spiral. The longer the termination line, the stronger in particular is the weakening of the signal guided in it. Due to a meandering or spiral design, it is then advantageously possible to design as long a termination line as possible in a particularly space-saving manner, in particular to arrange it in the second tier.

In some examples, the termination line includes a line end on which a through contact is arranged. The latter is designed for example as a Via. As a result, a short circuit is advantageously achieved on the end of the line, as a result of which a radiation of any possible signal residue present on the end of the line is advantageously reduced or entirely eliminated.

In some implementations, the termination line is designed as a stripline. In comparison with a micro-stripline, for example, a stripline is typically arranged in an intermediate chamber formed by two mass tiers and thus includes improved screening. A micro-stripline is by contrast usually only assigned one mass tier. This means that radiation of the signal guided by the stripline is reduced or entirely eliminated. As a result, interference of other construction elements arranged on the circuit board may be avoided.

The termination line may be arranged between the second and a third substrate layer. As a result, a signal guided by means of the termination line experiences a particularly high absorption and the effect of the wave termination is improved accordingly. In some examples, the second and third substrate layers are produced from the same material. As a result, the production costs of the circuit board are reduced accordingly.

In some implementations, on a side of the third substrate layer lying opposite the second tier, a second mass tier is arranged. In combination with the first mass tier it is in particular possible to design the termination line as a stripline in a simple manner. The termination line is then the stripline and the two mass tiers form a corresponding limitation in the vertical direction. Here, the second tier, which includes the termination line, is framed by the second and third substrate layer and the two substrate layers are in turn framed by the two mass areas.

In some examples, the circuit board is compiled as follows as a multiple layer system or a multiple layer circuit board as a stack with a stacking direction pointing in the vertical direction: first layer, first substrate layer, first mass tier, second substrate layer, second tier, third substrate layer, second mass tier. Here it is possible that one or more tiers, in particular the first tier and the second mass area, additionally include a paint layer or other protective layer applied to them. The latter is then in particular produced from an insulating material.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a schematic and profile depiction a radar system with a circuit board designed as a multiple layer circuit board,

FIG. 2 shows a schematic and perspective depiction a section of the circuit board according to FIG. 1 with a wave termination,

FIG. 3 shows a top view the section according to FIG. 2 and a first tier,

FIG. 4 shows a top view a first mass tier of the section according to FIG. 2,

FIG. 5 shows a top view a second layer of the section according to FIG. 2,

FIG. 6 shows a top view a second mass tier of the section according to FIG. 2, and

FIG. 7 shows a simulated and a measured reflection behaviour of the wave termination according to FIG. 2.

The dimensions and values named in the description below should merely be regarded as examples. Like reference symbols in the various drawings indicate like elements.

### DETAILED DESCRIPTION

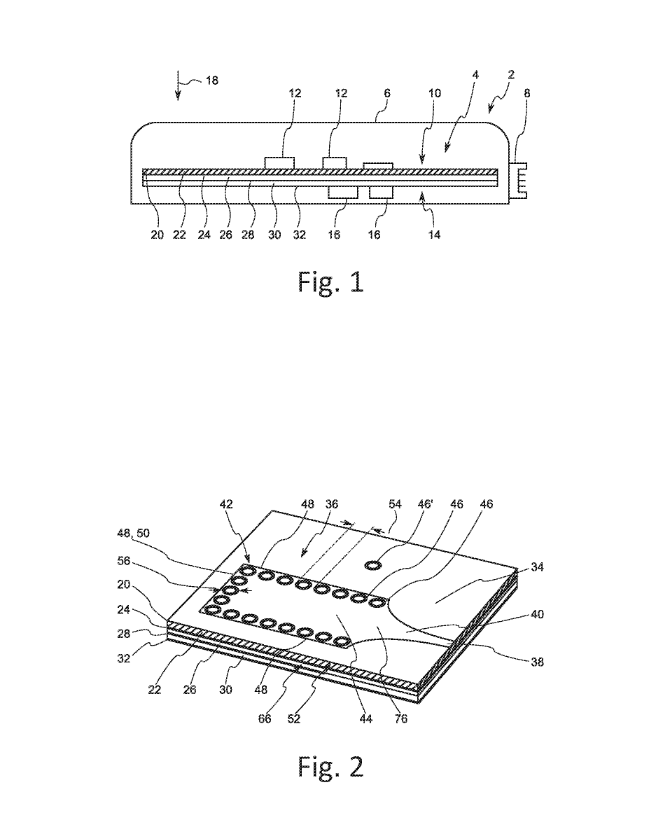

A radar system 2 with a circuit board 4 and a housing 6 is shown in FIG. 1. The radar system 2 is in particular suitable for use in a motor vehicle not shown here, for example, as a distance warning device. The radar system may include suitable transmission and receiving devices not shown further here, such as antennae. The housing 6 additionally includes a connection 8, via which the radar system 2 is for example connected to systems not shown here for the purpose of data exchange. The radar system 2 may be connected to a control and/or data processing system of the motor vehicle. Alternatively or in addition, the radar system 2 may include a control facility not shown in greater detail, such as for the purpose of evaluating data or a control of the radar system 2.

The circuit board 4 includes an upper side 10 on which a number of HF components 12 is arranged, and an underside 14 on which additional electronic components 16 are arranged. In some examples, the circuit board 4 is a multiple layer system and includes several tiers and substrate layers which form a stack. The circuit board 4 shown in FIG. 1 includes in the stacking direction 18, i.e., starting with the upper side 10 and in the direction of the underside 14 (or also from top to bottom) the following tiers and substrate layers: a first tier 20, a first substrate layer 22 (shown as shaded here), a first mass tier 24, a second substrate layer 26, a second tier 28, a third substrate layer 30, and a second mass tier 32.

A section of the circuit board 4 according to FIG. 1 is shown in FIG. 2. In both figures, the multiple layer structure of the circuit board 4 can clearly be seen. The tiers 20, 24, 28, 32 are respectively produced form a conductive material (such as copper). Here, parts of the respective layer 20, 24, 28, 32, may be left out, i.e., a tier 20, 24, 28, 32 may also include areas 34 in which no conductive material is attached. For example, the two mass tiers 24, 32 are designed on the section shown essentially as areas made of conductive material; however, the two tiers 20, 28 include free areas in order to form line structures made of conductive material. The latter may be particularly clearly seen for the first tier 20, which here forms an external tier or top tier. Equally, the second tier 28 may include free areas; in FIG. 2 this is indicated by different line thickness of the second tier.

As shown, the first substrate layer 22 is produced from an HF material, for example a material known under the brand name RO3003; the second and third substrate layers 26, 30 are respectively produced from a standard material, and in some examples, both from the same material, such as the material known under the material name FR4. The materials are usually dielectric and respectively include a loss factor which represents a measure for the absorption behaviour of the respective material. Here the HF material a lower loss factor compared to the standard material, in particular for electromagnetic signals with a high frequency, for example from a frequency range between 10 GHz and 100 GHz. In other words, the first substrate layer 22 is low loss and the two remaining substrate layers 26, 30 are high loss. The first tier 20 attached to the first substrate layer 22 may serve to guide or transmit high frequency signals.

FIG. 2 shows a wave termination 36 which is connected to a signal line 38. This is only partially visible in FIG. 2 and runs further outside of the section shown. In some examples, the signal line 38 is designed as a micro-stripline. This serves to transmit a signal with a specified frequency. The signal may be high frequency, for example, the frequency is selected from a frequency range between 10 GHz and 100 GHz, and amounts to approximately 77 GHz, for example.

The signal line 38 is connected to a hollow line 42, which is a part of the wave termination 36, by means of a transition area 40 which here has a funnel shape. FIG. 2 merely shows a horizontal hollow line wall 44 of the hollow line 42. This hollow line wall 44, the transition area 40, and the signal line 38 are made of a conductive material and are attached as part of the first tier 20 onto the first substrate layer 22. Additionally, the first tier 20 is usually covered with a protective paint not shown here.

Further, a number of through contacts 46 may be seen, which are arranged in a U shape and in this manner form two side arms and a middle arm which connects these. The through contacts 46 extend in the stacking direction 18, as a result of which the side arms respectively form a vertical hollow line wall 48 of the hollow line 42; the middle arm in particular forms a closed end 50 of a first section 52 of the hollow line 42.

The through contacts 46 are at a specified distance 54 from each other and have a specified diameter 56. The distance 54 and the diameter 56 may be suitably selected in dependence on the frequency of the signal. For example, the distance 54 is approximately 0.5 mm and the diameter 56 is approximately 0.3 mm.

Additionally, a further through contact 46′ is arranged away from the through contacts 46. This is in particular designed according to the same manner as the through contacts 46. In some examples, the through contacts 46, 46′ are designed as so-called Vias, i.e., holes with metallised inner walls, for example, bore holes, and extend over all four tiers 20, 24, 28, 32 and through all three substrate layers 22, 26, 30. Alternatively, the holes are not only metallised on their inner walls, but are also completely filled out with conductive material, for example, a suitable pin is inserted into the hole.

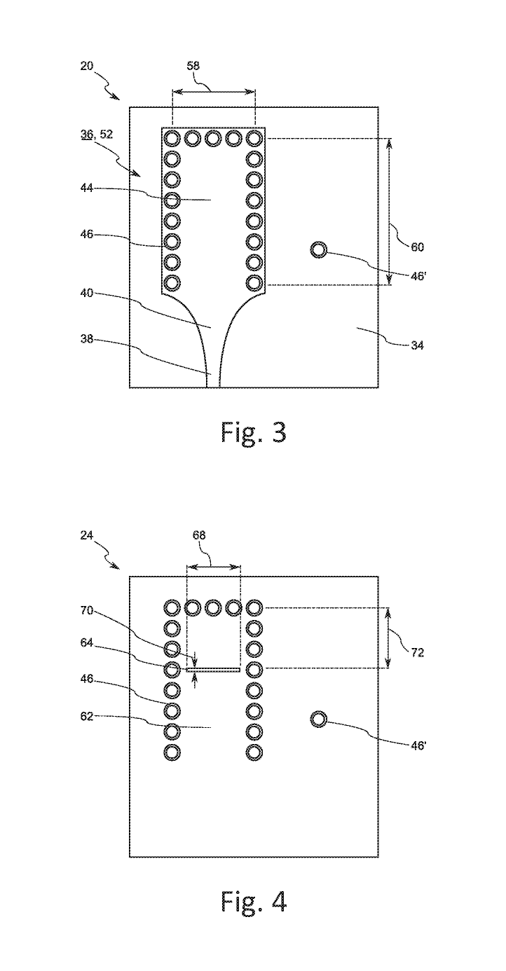

FIGS. 3 to 6 each show one of the four tiers 20, 24, 28, 32 in a top view. As shown, the wave termination 36 extends over several of the tiers 20, 24, 28, 32 and substrate layers 22, 26, 30 of the circuit board. The first layer 20 is shown in FIG. 3. The through contacts 46 forming the hollow line 42 arranged in a U-shape may be clearly seen, as can the transition area 40 which connects the signal line 38 with the hollow line 42.

The hollow line 42 has a width 58 and a length 60 that are specified by the arrangement of the through contacts 46. In a suitable manner, this arrangement and thus the width 58 and the length 60 of the hollow line 42 is selected depending on the frequency of the signal. For example, the width 58 is approximately 2 mm and the length 60 is approximately 3.5 mm.

FIG. 4 shows the mass tier 24 which follows the first substrate layer 22 in the stacking direction 18, which includes a horizontal hollow line wall 62 in the area of the through contacts 46 arranged in a U shape. This hollow line wall 62 in combination with the hollow line wall 44 formed in the first tier 20 and the through contacts 46 enclose a chamber area in the first substrate layer 22 and thus form the first section 52 of the hollow line 42. In some examples, as a result of the U-shaped arrangement of the through contacts 46 and the connection with the first mass tier 24, this section 52 is short circuited.

The first mass tier 24 may be produced in the section shown essentially entirely from conductive material; exceptions are only the through contacts 46 and an opening designed as a coupling slit 64. This coupling slit 64 is inserted into the horizontal hollow line wall 62 and in particular enables a coupling of the first section 52 with a second section 66 of the hollow line 42 arranged underneath. In other words, the signal coupled into the first section 52 of the hollow line 42 starting from the signal line 38 may be further transmitted by means of the coupling slit 64 into the second section 66. This is essentially arranged in the second substrate layer 26.

The coupling slit 64 is designed in such a manner that the signal may be transmitted in as reflection-free a manner as possible from the first section 52 into the second section 66. As shown in FIG. 4, the coupling slit 64 is designed as a rectangle with a slit width 68 that is less than the width 58 of the hollow line 42, and with a slit length 70 that is approximately one size less than the slit width 68. In some examples, the slit width 68 and/or the slit length 70 are selected depending on the frequency. For example, the slit width 68 is 1.4 mm and the slit length 70 is 0.1 mm. Further, the coupling slit 64 is arranged at a certain distance 72 from the closed end 50 of the hollow line 42 and is for example 1.5 mm, i.e., approximately half of the wavelength of a signal with a frequency of approximately 77 GHz.

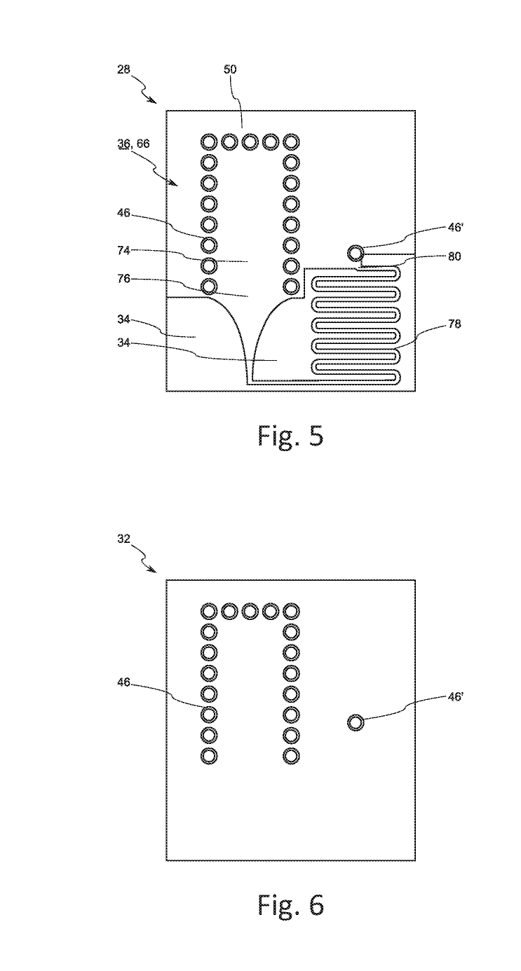

FIG. 5 shows the second tier 28 arranged in the stacking direction 18 below the second substrate layer 26. The through contacts 46 arranged in a U shape enclose a part of the second tier 28 which in this manner forms a horizontal line wall 74 of the horizontal line, in particular of the second section 66. This is consequently formed by means of the horizontal line walls 62, 74 and the through contacts 46 arranged in the second tier 28 and the first mass tier 24. As shown, the through contacts 46 accordingly form at the same time vertical hollow line walls 48 of the first and second section 52, 66. A hollow line 42 designed in this manner is particularly space saving in its design due to the sections 52, 66 arranged one on top of the other in the stacking direction 18. Here, the horizontal hollow line wall 52 formed in the first mass tier 24 serves both as a lower hollow line wall of the first section 52 and as an upper hollow line wall of the second section 66.

In some implementations, the two sections 52, 66 are not arranged one on top of the other (not shown). In particular, further through contacts 46 are then possibly required in order to form accordingly suitable hollow line walls 48. However, the first and second sections 52, 66 may overlap at least partially in the stacking direction 18, and in such a manner that these are connected by means of the coupling slit 64 for transmitting the signal.

Since the through contacts 46 in some examples, form vertical hollow line walls 48 of the first section 66, the latter is thus essentially formed in mirror symmetry to the first section 52 with regard to the first mass tier 24.

The second section 66 includes an open end 76 due to the U-shaped arrangement of the through contacts 46. This is connected by means of a further transition area 40 to a termination line 78, which is here designed as a so-called stripline. Since the termination line 78 is surrounded by the second and third substrate layer 26, 30, which are both respectively produced from a material with a high loss factor, the signal experiences accordingly high losses during transmission via the termination line 78. The longer the termination line 78, the greater the losses. In order to realise as long a termination line 78 as possible, while at the same time requiring little space, the line runs in an essentially meandering form in the variant shown in FIG. 5. In other examples, not shown here, the termination line 78 is however spiral in form.

The termination line 78 includes a line end 80 on which the through contact 46′ is arranged. On the one hand, this connects the line end 80 over a particularly short route to the two mass tiers 24, 32, while on the other offering access to the termination line 78 for the purpose of measuring transmission in order to determine the absorption effect of the wave termination 42.

FIG. 6 shows the second mass tier 32, which in the section shown is fully designed as a surface made of conductive material, with the exception of the through contacts 46, 46′. In particular, the second mass tier 32 like the first mass tier 24 includes conductive material throughout in the area below or above the termination line 78, as a result of which the termination line 78 is in particular designed as a stripline.

The through contacts 46, 46′ are designed to be continuous in the examples shown, in other words, they connect all four tiers 20, 24, 28, 32 with each other. In particular, in the section of the circuit board 4 shown here, the areas of the four tiers 20, 24, 28, 32 that are equipped with conductive material are connected to each other in an electrically conductive manner and are in particular short circuited with a mass potential.

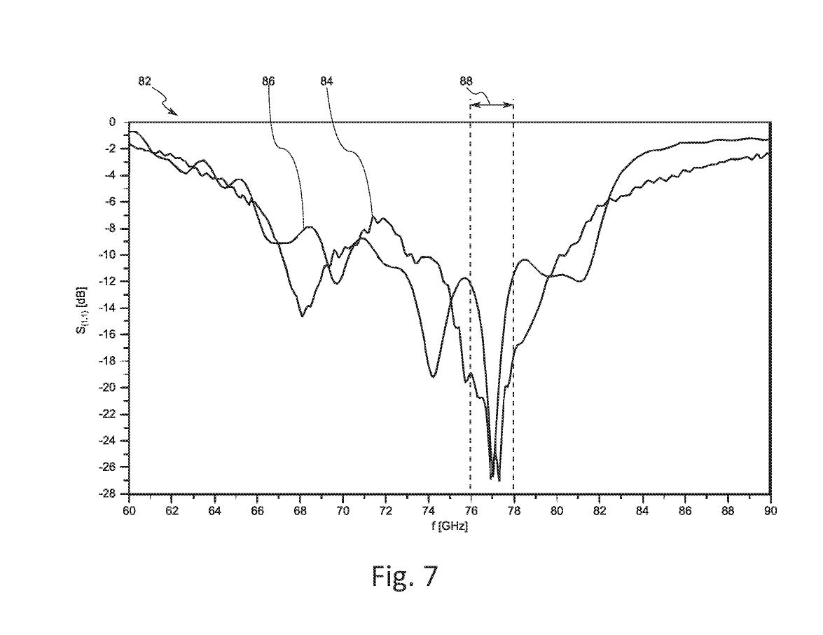

FIG. 7 shows a graph 82 with two curves 84, 86 for the purpose of clarifying the functionality of the wave termination 36. Here, functionality is intended to mean in particular a low reflection acceptance or absorption of a high frequency signal. While the input signal is being fed into the wave termination 36, a certain part is reflected and accordingly is present as an output signal. In order to determine a weakening achieved by means of the wave termination 36, respective signal strengths of the input and output signal are measured. The relationship between the signal strength of the output signal and the signal strength of the input signal then corresponds to a reflection parameter, in particular to a so-called S parameter (S_{1.1}). In the graph 82 the reflection parameter S_{1.1} is applied in decibels as a function of the frequency f of the input signal in Gigahertz. The reflection parameter S_{1.1} is applied along the coordinates of the graph 82, and the frequency f along the x-axis.

Here, the curve 84 shows a measurement result, while the curve 86 shows a simulation result. In both cases, a weakening in a target range 88 may clearly be seen, which here includes a frequency range of 76 GHz to 78 GHz. The wave termination 36 measured or simulated here has a particularly low reflection level with a frequency of approximately 77 GHz. In particular, both curves 84, 86 show a similar progression. The wave termination 36 shown here is therefore in particular suited for operation at a frequency of approximately 77 GHz. Due to suitable changes made accordingly to the various dimensions of the wave termination 36, it is advantageously possible to achieve at least a similar behaviour with other frequencies.

A number of implementations have been described. Nevertheless, it will be understood that various modifications may be made without departing from the spirit and scope of the disclosure. Accordingly, other implementations are within the scope of the following claims.

### LIST OF REFERENCE NUMERALS

2 Radar system
4 Circuit board
6 Housing
8 Connection
10 Upper side (of the circuit board)
12 HF component
14 Underside (of the circuit board)
16 Component
18 Stacking direction
20 First tier
22 First substrate layer
24 First mass tier
26 Second substrate layer
28 Second tier
30 Third substrate layer
32 Second mass layer
34 Free area
36 Wave termination
38 Signal line
40 Transition area
42 Hollow line
44 Hollow line wall (horizontal, in the first tier)
46 Through contact
46′ Through contact
48 Hollow line wall (vertical)
50 Closed end
52 First section (of the hollow line)
54 Distance (between two through contacts)
56 Diameter (of the through contact)
58 Width (of the hollow line)
60 Length (of the hollow line)
62 Hollow line wall (horizontal, in the first mass tier)
64 Coupling slit
66 Second section (of the hollow line)
68 Slit width
70 Slit length
72 Distance (coupling slit to closed end)
74 Hollow line wall (horizontal, second tier)
76 Open end
78 Termination line
80 Line end
82 Graph
84 Curve (measurement result)
86 Curve (simulation result)
88 Target range

What is claimed is:

1. A radar system for registering the environment of a motor vehicle, with a circuit board, the radar system comprising:
a wave termination with a termination line;
a signal line connected with this for the transmission of a high frequency signal;
a first substrate layer produced from a first material with a first loss factor;
a first tier attached onto the first substrate layer, the first tier includes the signal line;
a second substrate layer produced from a second material with a second loss factor which is greater than the first loss factor; and
a second tier attached onto the second substrate layer, the second tier includes the termination line.

2. The radar system of claim 1, wherein the termination line and the signal line are connected by means of a hollow line.

3. The radar system of claim 2, wherein the hollow line comprises a first section arranged in the first substrate layer and a second section arranged in the second substrate layer.

4. The radar system of claim 1, further comprising a first mass tier arranged between the first and the second substrate layers.

5. The radar system of claim 4, further comprising a coupling slit inserted into the first mass tier.

6. The radar system of claim 4, wherein the first layer, the second layer, and the first mass layer are connected by means of a number of through contacts.

7. The radar system of claim 6, wherein the through contacts form a hollow line wall of the hollow line.

8. The radar system of claim 6, wherein the through contacts are arranged in a U shape.

9. The radar system of claim 1, wherein the termination line is designed in a meandering form.

10. The radar system of claim 1, wherein the termination line comprises a line end on which a through contact is arranged.

11. The radar system of claim 1, wherein the termination line is designed as a stripline.

12. The radar system of claim 1, wherein the termination line is arranged between the second and a third substrate layer.

13. The radar system of claim 12, wherein the second and third substrate layers are produced from the same material.

14. The radar system of claim 12, wherein on the side of the third substrate layer opposite the second tier, a second mass tier is arranged.

15. A circuit board for a radar system of claim 1, the circuit board comprising:
a wave termination with a termination line;
a signal line connected with this for the transmission of a high frequency signal;
a first substrate layer produced from a first material with a first loss factor;
a first tier attached onto the first substrate layer, which comprises the signal line;
a second substrate layer produced from a second material with a second loss factor which is greater than the first loss factor; and
a second tier attached onto the second substrate layer, which comprises the termination line.
